(19) United States
(12) Patent Application Publication
(10) Pub. No.: US 2007/0217248 A1
(43) Pub. Date: Sep. 20, 2007

(54) Standby circuitry for fuse cell

(76) Inventors: Zhanping Chen, Portland, OR (US); Jun He, Portland, OR (US); Jeffrey Hicks, Banks, OR (US); Mathew Nazareth, El Dorado Hills, CA (US)

Correspondence Address: SCHWABE, WILLIAMSON & WYATT, P.C., PACWEST CENTER, SUITE 1900, 1211 S.W. FIFTH AVE., PORTLAND, OR, 97204, US

(21) Appl. No.: 11/377,141

(22) Filed: Mar. 15, 2006

(51) Int. Cl. G11C 17/00

(52) U.S. Cl. 365/96

(57) ABSTRACT

An apparatus, a method, and a system for a fuse cell are disclosed herein. In various embodiments, a fuse cell may comprise a standby circuitry to reduce a voltage drop across a fuse device.

### TECHNICAL FIELD

Embodiments of the invention relate generally to the field of integrated circuit design, specifically to methods, apparatuses, and systems associated with and/or having fuse cells.

### BACKGROUND

Increasingly, metal fuses are being incorporated into integrated circuit design. These types of metal fuses may be formed by running a sustained large current through a metal line eventually resulting in a void or open in the metal line. The void or open creates an increased resistance.

After programming, a fuse cell comprising one or more fuses is generally in either a sensing or standby mode. Sensing generally only happens during power on and reset. However, after sensing, a fuse cell may be in a standby mode for sustained periods of time. During a standby mode, a large voltage drop may be present across the fuse which may cause electrons in certain metal species to migrate and gradually reduce the resistance of the programmed fuse. This reduced resistance may eventually lead to fuse cell state flipping and/or circuit malfunctioning.

### BRIEF DESCRIPTION OF THE DRAWINGS

Embodiments of the present invention will be readily understood by the following detailed description in conjunction with the accompanying drawings. Embodiments of the invention are illustrated by way of example and not by way of limitation in the figures of the accompanying drawings.

FIG. 1 illustrates a fuse cell with a standby circuitry incorporated with the teachings of the present invention, in accordance with various embodiments;

FIG. 2 illustrates another fuse cell with a standby circuitry incorporated with the teachings of the present invention, in accordance with various embodiments;

FIG. 3 illustrates a system incorporated with the teachings of the present invention, in accordance with various embodiments; and

FIG. 4 illustrates a method incorporated with the teachings of the present invention, in accordance with various embodiments.

### DETAILED DESCRIPTION OF EMBODIMENTS OF THE INVENTION

Illustrative embodiments of the present invention include but are not limited to methods for prediction-based processing, components contributing to the practice of these methods, in part or in whole, and systems endowed with such components.

In the following detailed description, reference is made to the accompanying drawings which form a part hereof and in which is shown by way of illustration embodiments in which the invention may be practiced. It is to be understood that other embodiments may be utilized and structural or logical changes may be made without departing from the scope of the present invention. Therefore, the following detailed description is not to be taken in a limiting sense, and the scope of embodiments in accordance with the present invention is defined by the appended claims and their equivalents.

Various operations may be described as multiple discrete operations in turn, in a manner that may be helpful in understanding embodiments of the present invention; however, the order of description should not be construed to imply that these operations are order dependent.

The description may use perspective-based descriptions such as up/down, back/front, and top/bottom. Such descriptions are merely used to facilitate the discussion and are not intended to restrict the application of embodiments of the present invention.

The description may use the phrases “in an embodiment,” or “in embodiments,” which may each refer to one or more of the same or different embodiments. Furthermore, the terms “comprising,” “including,” “having,” and the like, as used with respect to embodiments of the present invention, are synonymous.

The phrase “A/B” means “A or B”. The phrase “A and/or B” means “(A), (B), or (A and B)”. The phrase “at least one of A, B and C” means “(A), (B), (C), (A and B), (A and C), (B and C) or (A, B and C)”. The phrase “(A) B” means “(B) or (A B)”, that is, A is optional.

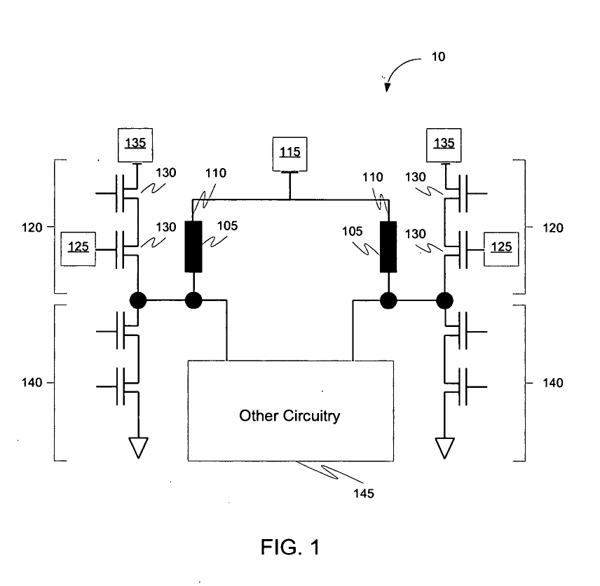

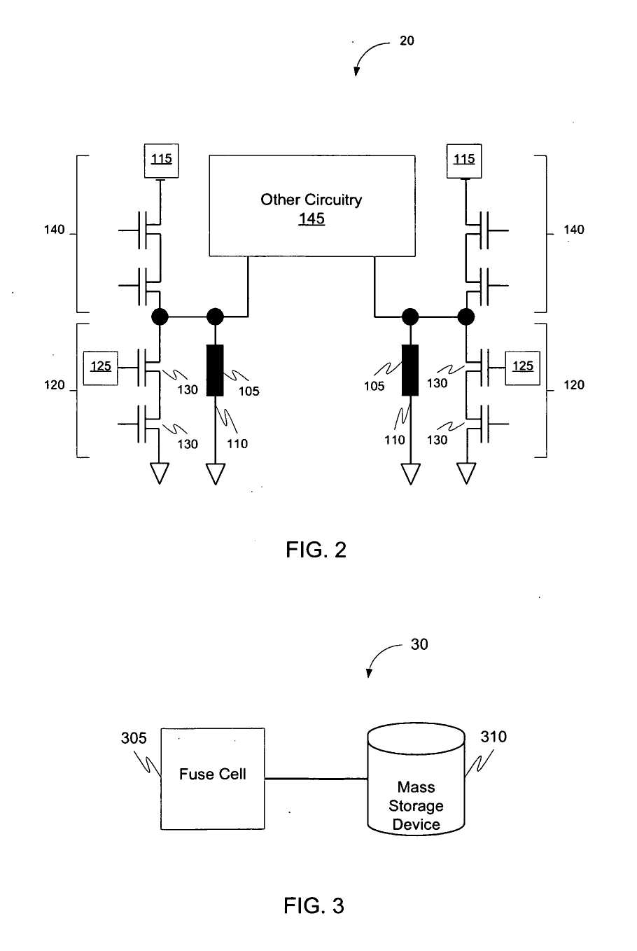

Referring now to FIG. 1 and FIG. 2, illustrated are embodiments of a fuse cell 10 comprising a standby circuitry 120 in accordance with various embodiments of the present invention. As shown in FIG. 1, for the embodiments, fuse cell 10 may comprise a fuse device 105 having a terminal 110 configured to receive a supply voltage from a supply voltage source 115. Further, in these embodiments, fuse cell 10 may also comprise a standby circuitry 120 coupled to the fuse device 105.

Standby circuitry 120 may be variously configured. For example, in some embodiments, standby circuitry 120 may be configured to provide a standby supply voltage to the fuse device 105 when the fuse cell 10 is in a standby mode to reduce a voltage drop value across the fuse device 105. In various ones of these embodiments, standby circuitry 120 may be configured to reduce the voltage drop value across fuse device 105 to the threshold voltage value of one or more switchable conductive path devices 130 of the standby circuitry 120. For example, if the supply voltage and one or more switchable conductive path devices 130 of standby circuitry 120 have a threshold value, providing a standby supply voltage to fuse device 105 using the standby circuitry 120 may reduce the voltage drop value across fuse device 105 to the threshold voltage value.

Still further, in various embodiments, standby circuitry 120 may be coupled to a standby signal source 125. In some of these embodiments, standby circuitry 120 may be coupled to a standby signal source 125 to receive a standby signal from the standby signal source 125 to indicate to the standby circuitry 120 that fuse cell 10 is in standby mode. As mentioned earlier, fuse cell 10 may be configured to provide a standby supply voltage to fuse device 105 when the fuse cell 10 is in standby mode to reduce a voltage drop value across fuse device 105.

In some embodiments and as shown if FIG. 1, standby circuitry 120 may include one or more switchable conductive path devices 130. Switchable conductive path device 130 may be, in various embodiments, either a PMOS transistor device or an NMOS device. In some of these embodiments, switchable conductive path device 130 may be coupled to the standby signal source 125 to receive a standby signal, as discussed previously. In various ones of these embodiments, switchable conductive path device 130 may be configured to switch on when switchable conductive path device 130 receives a standby signal. For example, switchable conductive path device 130 may be configured to switch on when switchable conductive path device 130 receives a logic-high standby signal. Still further, in various embodiments, switchable conductive path device 130 may be configured to switch off during certain processes. For example, switchable conductive path device 130 may be configured to switch off during programming and/or reading of fuse device 105.

In some of these embodiments, standby circuitry 120 may further include another switchable conductive path device 130. In various ones of these embodiments, the two switchable conductive path devices 130 may be NMOS transistor devices serially arranged between another supply voltage source 135 and the fuse device 105. In these embodiments, a first of the NMOS transistor devices may be configured to receive another supply voltage from the other supply voltage source 135, and a second of the NMOS transistor devices may be configured to provide the standby supply voltage to the fuse device 105. This stacking configuration may be used for various reasons including, for example, increasing tolerance to high voltages. In various embodiments and depending on the applications, supply voltage sources 115 and 135 may be the same supply voltage source or may be different supply voltage sources.

In various embodiments, fuse cell 10 may also comprise various programming circuitry 140 and/or other circuitry 145. Other circuitry 145 may include, for example, sense amplifier circuitry. In some embodiments and as shown in FIG. 2, fuse cell 20 may comprise other circuitry 145. In still other embodiments, various circuitry devices and/or design topologies that may be enlisted, depending on the desired use and function of fuse cell 10. As shown in FIG. 1 and FIG. 2, for example, fuse cell 10 may comprise two or more fuse devices 105, each fuse device 105 coupled to programming circuitry 140.

Referring now to FIG. 3, illustrated is a system 30 incorporated with the teachings of the present invention, in accordance with various embodiments. As shown and in accordance with various embodiments, system 30 may comprise one or more fuse cells 305 and one or more mass storage devices 310 coupled to fuse cells 305. In various ones of these embodiments, fuse cell 305 may comprise a fuse device and a standby circuitry coupled to the fuse device (not shown). In various ones of these embodiments, standby circuitry may be configured to provide a standby supply voltage to the fuse device when the fuse cell 305 is in a standby mode to reduce a voltage drop value across fuse device.

Systems 30 in accordance with various embodiments of the present invention may be variously configured. For example, standby circuitry may be variously configured. In various embodiments, standby circuitry may be configured to reduce the voltage drop value across fuse device to the threshold voltage value of the standby circuitry. Still further, in various embodiments, standby circuitry may be coupled to a standby signal source. In some of these embodiments, standby circuitry may be coupled to a standby signal source to receive a standby signal from the standby signal source to indicate to the standby circuitry the fuse cell 305 is in standby mode. As mentioned earlier, fuse cell 305 may be configured to provide a standby supply voltage to fuse device when the fuse cell 305 is in standby mode to reduce a voltage drop value across a fuse device.

In some embodiments, standby circuitry in accordance with the present invention may include one or more switchable conductive path devices. In various embodiments, switchable conductive path device may be either a PMOS transistor device or an NMOS device. In some of these embodiments, switchable conductive path device may be coupled to the standby signal source to receive a standby signal. In various ones of these embodiments, switchable conductive path device may be configured to switch on when switchable conductive path device receives a standby signal. For example, switchable conductive path device may be configured to switch on when switchable conductive path device receives a logic-high standby signal. Still further, in various embodiments, switchable conductive path device may be configured to switch off during certain processes. For example, switchable conductive path device may be configured to switch off during programming and/or reading of fuse device.

In various other embodiments, standby circuitry may further include another switchable conductive path device. In various ones of these embodiments, the two switchable conductive path devices may be NMOS transistor devices serially arranged between another supply voltage source and the fuse device. In these embodiments, a first of the NMOS transistor devices may be configured to receive another supply voltage from the other supply voltage source, and a second of the NMOS transistor devices may be configured to provide the standby supply voltage to the fuse device.

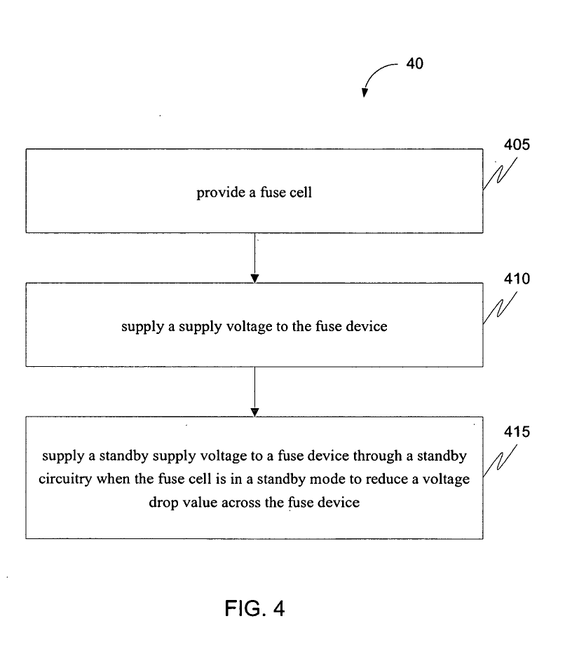

Illustrated in FIG. 4 is a method 40 in accordance with various embodiments of the present invention. As shown and in various embodiments, method 40 may comprise providing a fuse cell 405, supplying a supply voltage to the fuse device 410, and supplying a standby supply voltage to a fuse device through a standby circuitry when the fuse cell is in a standby mode to reduce a voltage drop value across the fuse device 415. In various ones of these embodiments, providing a fuse cell 405 may comprise providing a fuse cell having a fuse device and a standby circuitry coupled to the fuse device.

Embodiments of methods in accordance with the present invention may further comprise reducing the voltage drop value across the fuse device to a threshold voltage value of the standby circuitry. As mentioned previously, reducing the voltage drop value across the fuse device to a threshold voltage value of standby circuitry may be done, for example, by providing a supply voltage to a fuse device, and providing a standby supply voltage to fuse device using the standby circuitry.

In some embodiments, method 40 may further comprise sending a standby signal to the standby circuitry to indicate to the standby circuitry the fuse cell is in standby mode. In various ones of these embodiments, standby signal may be sent to a switchable conductive path device of standby circuitry. In various ones of these embodiments, standby signal may be sent to a PMOS transistor device or an NMOS transistor device of standby circuitry. In these embodiments, sending a standby signal to a switchable conductive path device of the standby circuitry may comprise switching on the switchable conductive path device. In still other embodiments, the method may further comprise switching off switchable conductive path device during programming and/or reading of fuse device.

Although certain embodiments have been illustrated and described herein for purposes of description of the preferred embodiment, it will be appreciated by those of ordinary skill in the art that a wide variety of alternate and/or equivalent embodiments or implementations calculated to achieve the same purposes may be substituted for the embodiments shown and described without departing from the scope of the present invention. Those with skill in the art will readily appreciate that embodiments in accordance with the present invention may be implemented in a very wide variety of ways. This application is intended to cover any adaptations or variations of the embodiments discussed herein. Therefore, it is manifestly intended that embodiments in accordance with the present invention be limited only by the claims and the equivalents thereof.

1. A fuse cell, comprising:
a fuse device having a terminal being configured to receive a supply voltage from a supply voltage source; and
a standby circuitry coupled to the fuse device, and configured to provide a standby supply voltage to the fuse device when the fuse cell is in a standby mode to reduce a voltage drop value across the fuse device.

2. The fuse cell of claim 1, wherein the standby circuitry has a threshold value, and the standby circuitry is configured to reduce the voltage drop value across the fuse device to the threshold voltage value of the standby circuitry.

3. The fuse cell of claim 1, wherein the standby circuitry is coupled to a standby signal source to receive the standby signal from the standby signal source to indicate to the standby circuitry the fuse cell is in the standby mode.

4. The fuse cell of claim 3, wherein the standby circuitry includes a switchable conductive path device coupled to the standby signal source to receive the standby signal.

5. The fuse cell of claim 4, wherein the switchable conductive path device is configured to switch on when the switchable conductive path device receives the standby signal.

6. The fuse cell of claim 5, wherein the switchable conductive path device is further configured to switch off during a selected one of programming of the fuse device and reading of the fuse device.

7. The fuse cell of claim 4, wherein the switchable conductive path device is either a PMOS or an NMOS transistor device.

8. The fuse cell of claim 4, wherein the standby circuitry further includes another switchable conductive path device, the two switchable conductive path devices being NMOS transistor devices arranged to provide a serial current path between another supply voltage source and the fuse device.

9. The fuse cell of claim 8, wherein a first of the NMOS transistor devices is configured to receive another supply voltage from the other supply voltage source, and a second of the NMOS transistor devices is configured to provide the standby supply voltage to the fuse device.

10. A method, comprising:
providing a fuse cell having:
a fuse device; and
a standby circuitry coupled to the fuse device; and
supplying a supply voltage to the fuse device; and
supplying a standby supply voltage to the fuse device through the standby circuitry when the fuse cell is in a standby mode to reduce a voltage drop value across the fuse device.

11. The method of claim 10, further comprising reducing the voltage drop value across the fuse device to a threshold voltage value of the standby circuitry.

12. The method of claim 10, further comprising sending a standby signal to the standby circuitry to indicate to the standby circuitry the fuse cell is in the standby mode.

13. The method of claim 12, wherein sending a standby signal to the standby circuitry comprises sending a standby signal to a switchable conductive path device of the standby circuitry to indicate to the standby circuitry the fuse cell is in the standby mode.

14. The method of claim 13, wherein sending a standby signal to the switchable conductive path device of the standby circuitry comprises switching on the switchable conductive path device.

15. The method of claim 14, further comprising switching off the switchable conductive path device during a selected one of programming of the fuse device and reading of the fuse device.

16. The method of claim 13, wherein sending a standby signal to a switchable conductive path device of the standby circuitry comprises sending a standby signal to either a PMOS or an NMOS transistor device.

17. A system, comprising:
a fuse cell, having:
a fuse device having a terminal being configured to receive a supply voltage from a supply voltage source; and
a standby circuitry coupled to the fuse device, and configured to provide a standby supply voltage to the fuse device when the fuse cell is in a standby mode to reduce a voltage drop value across the fuse device; and
one or more mass storage devices coupled to the fuse cell.

18. The system of claim 17, wherein the standby circuitry has a threshold value, and the standby circuitry is configured to reduce the voltage drop value across the fuse device to the threshold voltage value of the standby circuitry.

19. The system of claim 17, wherein the standby circuitry is coupled to a standby signal source to receive the standby signal from the standby signal source to indicate to the standby circuitry the fuse cell is in the standby mode.

20. The system of claim 19, wherein the standby circuitry includes a switchable conductive path device coupled to the standby signal source to receive the standby signal.

21. The system of claim 20, wherein the switchable conductive path device is configured to switch on when the switchable conductive path device receives the standby signal.

22. The system of claim 21, wherein the switchable conductive path device is further configured to switch off during a selected one of programming of the fuse device and reading of the fuse device.

23. The system of claim 20, wherein the switchable conductive path device is either a PMOS or an NMOS transistor device.

24. The system of claim 20, wherein the standby circuitry further includes another switchable conductive path device, the two switchable conductive path devices being NMOS transistor devices arranged to provide a serial current path between another supply voltage source and the fuse device.

25. The system of claim 24, wherein a first of the NMOS transistor devices is configured to receive another supply voltage from the other supply voltage source, and a second of the NMOS transistor devices is configured to provide the standby supply voltage to the fuse device.
